(19) United States
(12) Patent Application Publication
(10) Pub. No.: US 2026/0262467 A1
(43) Pub. Date: Sep. 3, 2026

(54) Film Forming Apparatus and Film Forming Method

(71) Applicant: Tokyo Electron Limited, Tokyo (JP)

(72) Inventors: Keisuke SATO, Yamanashi (JP); Toru KITADA, Yamanashi (JP); Atsushi GOMI, Yamanashi (JP); Kanto NAKAMURA, Yamanashi (JP)

(21) Appl. No.: 19/656,602

(22) Filed: Apr. 23, 2026

Related U.S. Application Data
(62) Division of application No. 17/854,944, filed on Jun. 30, 2022, now abandoned.

(30) Foreign Application Priority Data
Jul. 1, 2021 (JP) 2021-110267

(51) Int. Cl. H10P 72/00; H10B 61/00; H10N 50/80

(52) U.S. Cl. CPC H10P 72/0468; H10P 72/0432; H10P 72/0454; H10B 61/00; H10N 50/80

(57) ABSTRACT

A film forming apparatus for forming a laminated structure on a substrate to form a magnetic tunnel junction element is disclosed. The film forming apparatus comprises: a plurality of processing chambers where a magnetic layer and an insulating layer are formed on the substrate; a heat treatment chamber where a magnetic field is applied to the substrate to perform heat treatment; a vacuum transfer chamber that connects the processing chambers and the heat treatment chamber; and a controller.

### CROSS-REFERENCE TO RELATED APPLICATIONS

This application is a divisional application of U.S. Patent Application No. 17/854,944 filed on June 30, 2022, which claims priority to and the benefit of Japanese Patent Application No. 2021-110267, filed on July 1, 2021, the disclosures of all of which are incorporated herein by reference in their entirety.

### TECHNICAL FIELD

The present disclosure relates to a film forming apparatus and a film forming method.

### BACKGROUND

A magnetic tunnel junction (MTJ) element used in a magnetoresistive random access memory (MRAM) is configured as a laminated structure having two magnetic layers and a tunnel barrier layer that is an insulating layer disposed therebetween.

Japanese Laid-open Patent Publication No. 2021-47074 discloses that a laminated film is formed on a wafer by a film forming system and, then, heat treatment is performed on the wafer taken out from the film forming system.

### SUMMARY

When the two magnetic films and the insulating film are annealed and crystallized, boron in the magnetic film is diffused. Accordingly, the performance of the MTJ element may deteriorate.

In view of the above, one aspect of the present disclosure provides a film forming apparatus and a film forming method for improving characteristics of a magnetic tunnel junction element.

To this end, a film forming apparatus for forming a laminated structure on a substrate to form a magnetic tunnel junction element is provided, which comprises a plurality of processing chambers where a magnetic layer and an insulating layer are formed on the substrate; a heat treatment chamber where a magnetic field is applied to the substrate to perform heat treatment; a vacuum transfer chamber that connects the processing chambers and the heat treatment chamber; and a controller.

### BRIEF DESCRIPTION OF THE DRAWINGS

The objects and features of the present disclosure will become apparent from the following description of embodiments, given in conjunction with the accompanying drawings, in which:

FIG. 1 is a plan view showing a configuration of an example of a substrate processing system;

FIG. 2 is an exemplary flowchart showing an MTJ element forming process;

FIGS. 3A to 3D show exemplary cross-sectional views of the formed element; and

FIG. 4 is a cross-sectional view showing a configuration example of a magnetic field annealing device.

### DETAILED DESCRIPTION

Hereinafter, embodiments for implementing the present disclosure will be described with reference to the accompanying drawings. Like reference numerals will be given to like parts throughout the drawings, and redundant description may be omitted.

### SUBSTRATE PROCESSING SYSTEM 100

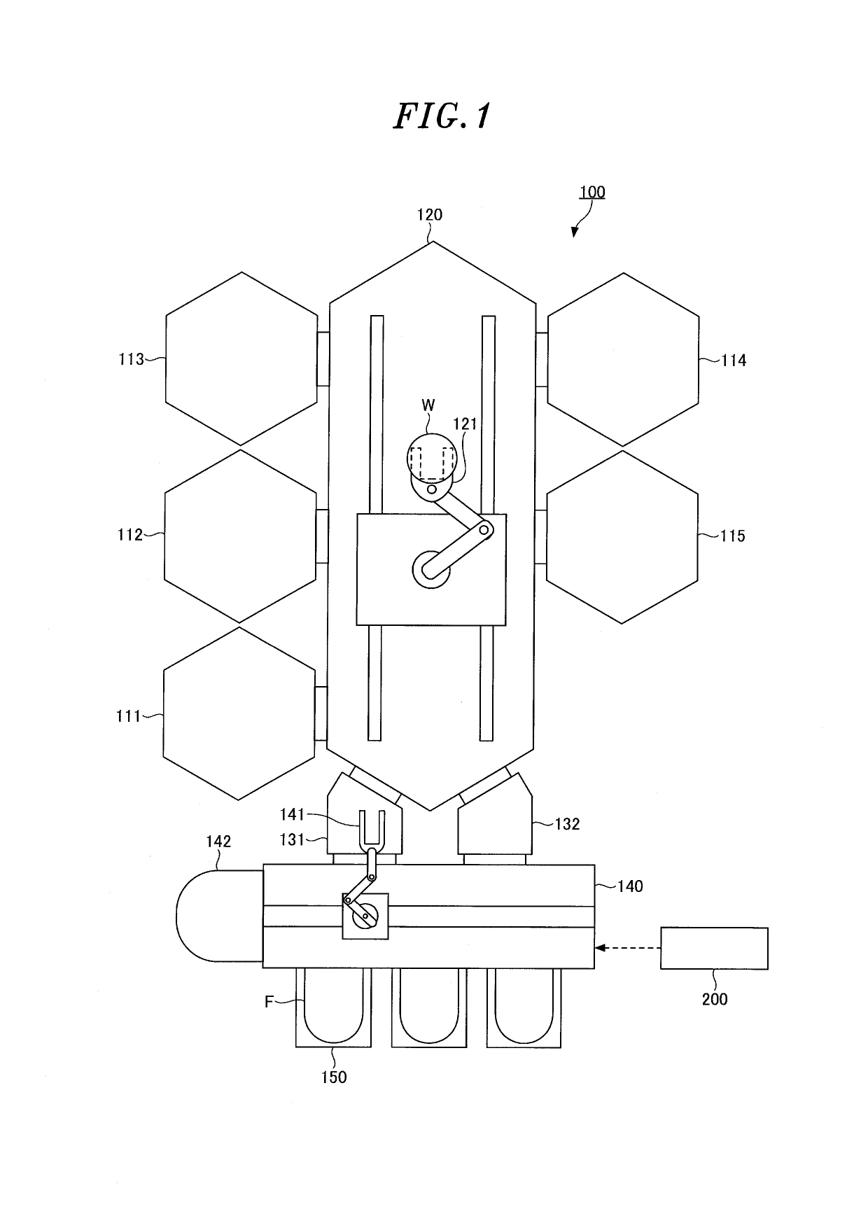

An example of an overall configuration of a substrate processing system (film forming apparatus) 100 will be described with reference to FIG. 1. FIG. 1 is a plan view showing a configuration of an example of the substrate processing system 100.

The substrate processing system 100 shown in FIG. 1 is a system having a cluster structure (multi-chamber type system). The substrate processing system 100 includes a plurality of processing chambers 111 to 115, a vacuum transfer chamber 120, load-lock chambers 131 and 132, an atmospheric transfer chamber 140, a load port 150, and a controller 200.

The processing chambers (vacuum processing devices) 111 to 115 are depressurized to a predetermined vacuum atmosphere, and desired processing (cleaning, etching, film formation, magnetic field annealing, or the like) is performed on a wafer (substrate) W in the processing chambers 111 to 115. The processing chambers 111 to 115 are arranged adjacent to the vacuum transfer chamber 120. The processing chambers 111 to 115 and the vacuum transfer chamber 120 communicate with each other by opening and closing gate valves. Each of the processing chambers 111 to 115 has a mount table on which the wafer W is placed. The operations of individual components for performing processing in the processing chambers 111 to 115 are controlled by the controller 200.

The vacuum transfer chamber 120 is connected to the plurality of chambers (the processing chambers 111 to 115 and the load-lock chambers 131 and 132) through gate valves, and is depressurized to a predetermined vacuum atmosphere. Further, a vacuum transfer device 121 for transferring the wafer W is disposed in the vacuum transfer chamber 120. The vacuum transfer device 121 transfers the wafer W between the processing chambers 11 to 115 and the vacuum transfer chamber 120 by opening and closing gate valves of the processing chambers 111 to 115. Further, the vacuum transfer device 121 loads and unloads the wafer W between the load-lock chambers 131 and 132 and the vacuum transfer chamber 120 by opening and closing gate valves of the load-lock chambers 131 and 132. The operation of the vacuum transfer device121 and the opening/closing of the gate valves are controlled by the controller 200.

The load-lock chambers 131 and 132 are disposed between the vacuum transfer chamber 120 and the atmospheric transfer chamber 140. Each of the load-lock chambers 131 and 132 has a mount table (not shown) on which the wafer W is placed. The load-lock chambers 131 and 132 can be switched between an atmospheric atmosphere and a vacuum atmosphere. The load-lock chambers 131 and 132 and the vacuum transfer chamber 120 in a vacuum atmosphere communicate with each other by opening and closing gate valves. The load-lock chambers 131 and 132 and the atmospheric transfer chamber 140 in an atmospheric atmosphere communicate with each other by opening and closing door valves. The switching between the vacuum atmosphere and the atmospheric atmosphere in the load-lock chambers 131 and 132 is controlled by the controller 200.

The atmospheric transfer chamber 140 has an atmospheric atmosphere, and a downflow of clean air is formed therein, for example. Further, an atmospheric transfer device 141 for transferring the wafer W is disposed in the atmospheric transfer chamber 140. Further, the atmosphere transfer chamber 140 is provided with an aligner 142 for aligning the wafer W.

Further, the load port 150 is disposed on a wall surface of the atmosphere transfer chamber 140. A carrier F containing a wafer W or an empty carrier F is attached to the load port 150. For example, a front opening unified pod (FOUP) or the like can be used as the carrier F.

The atmospheric transfer device 141 loads and unloads the wafer W between the load-lock chambers 131 and 132 and the atmospheric transfer chamber 140 by opening and closing the door valves. Further, the atmospheric transfer device 141 loads and unloads the wafer W between the aligner 142 and the atmospheric transfer chamber 140. Further, the atmospheric transfer device 141 loads and unloads the wafer W between the carrier F attached to the load port 150 and the atmospheric transfer chamber 140. The operation of the atmospheric transfer device 141 and the opening and closing of the door valves are controlled by the controller 200.

The controller 200 includes a central processing unit (CPU), a read only memory (ROM), a random access memory (RAM), and a hard disk drive (HDD). The controller 200 is not limited to the HDD, and may have another storage area such as a solid state drive (SSD), or the like. A recipe in which a processing sequence, process conditions, and transfer conditions are set is stored in the storage area of the HDD, the RAM, or the like.

The CPU controls the processing of the wafer W in each of the processing chambers 111 to 115 based on the recipe, to control the transfer of the wafer W. The HDD or the RAM may store a program for executing the processing of the wafer W or the transfer of the wafer W in the processing chambers 111 to 115. The program may be provided while being stored in the storage medium, or may be provided from an external device through a network.

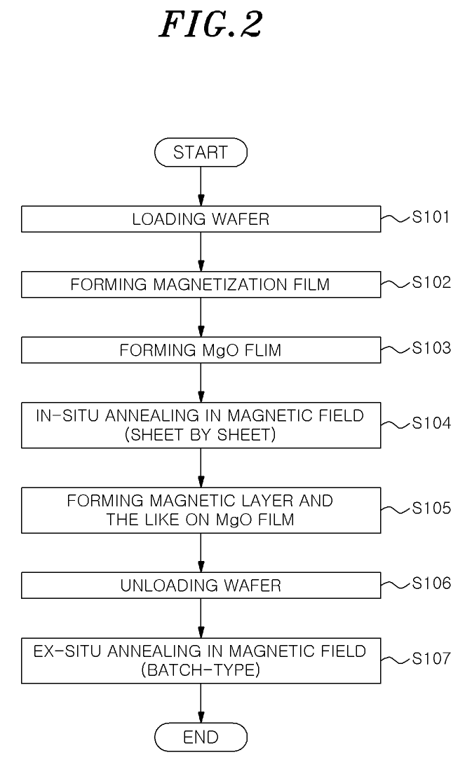

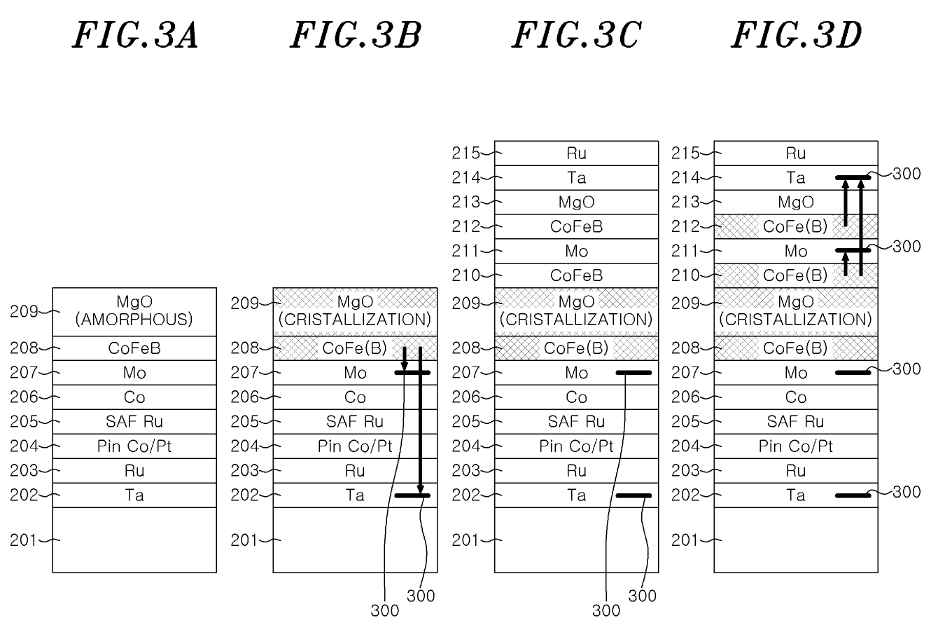

Next, a method of forming a magnetic tunnel junction (MTJ) element used for a magnetoresistive random access memory (MRAM) on the wafer W will be described with reference to FIGS. 2 and 3A to 3D. FIG. 2 is an example of a flowchart illustrating an MTJ element forming process. FIGS. 3A to 3D are exemplary cross-sectional views of the formed element.

In step S101, the wafer W is loaded into the substrate processing system 100. For example, the carrier F accommodating an unprocessed wafer W is attached to the load port 150.

In step S102, a magnetization film 208 is formed on the wafer W. For example, the controller 200 controls the atmospheric transfer device 141 and the vacuum transfer device 121 to transfer an unprocessed wafer W to the processing chamber 111. The processing chamber 111 is, e.g., a physical vapor deposition (PVD) device, and a film is formed on the wafer W in the processing chamber 111. The controller 200 controls the processing chamber 111 such that a desired laminated film is formed on the wafer W.

In step S103, an MgO film 209 as a tunnel barrier film (insulating film) is formed on the magnetization film 208. For example, the controller 200 controls the vacuum transfer device 121 to transfer the wafer W from the processing chamber 111 to the processing chamber 112. The processing chamber 112 is, e.g., a PVD device, and a film is formed on the wafer W in the processing chamber 112. The controller 200 controls the processing chamber 112 such that the MgO film 209 is formed on the wafer W.

FIG. 3A is a schematic diagram illustrating laminated films on the wafer W after the completion of step S103. An electrode 201, a base layer (a Ta layer 202 and an Ru layer 203), a first magnetic layer 204, a spacer layer 205, a second magnetic layer (a Co layer 206, an Mo layer 207, and a CoFeB layer 208), and a tunnel barrier layer (the MgO film 209) are formed on the wafer W.

The electrode 201 is formed on the wafer W. The base layer is formed on the electrode 201. The base layer is formed by laminating the Ta layer 202 and the Ru layer 203, for example.

A fixed layer (first magnetic layer) having a synthetic antiferromagnet (SAF) structure is formed on the base layer. The fixed layer includes the first magnetic layer 204, the spacer layer 205, and the second magnetic layer (the Co layer 206, the Mo layer 207, and the CoFeB layer 208). The first magnetic layer 204 is formed on the base layer. The first magnetic layer 204 forms an antiferromagnetic bond with the second magnetic layer via the non-magnetic spacer layer 205, and fixes the magnetization direction of the second magnetic layer. The first magnetic layer 204 is formed as a multilayer film in which a Co film and a Pt film are alternately laminated. The non-magnetic spacer layer 205 is formed on the first magnetic layer 204. The spacer layer 205 is made of, e.g., Ru or the like. The second magnetic layer is formed on the spacer layer 205. The second magnetic layer is formed by laminating the Co layer 206, the Mo layer 207, and the CoFeB layer 208, for example.

The MgO film 209 as the tunnel barrier layer (insulating layer) is formed on the second magnetic layer (the CoFeB layer 208). The film formation temperature of the MgO film 209 in step S103 is, e.g., 150°C.

Here, the CoFeB layer 208 and the MgO film 209 formed by the PVD device have an amorphous structure.

In step S104, In-situ annealing is performed in a magnetic field. For example, the controller 200 controls the vacuum transfer device 121 to transfer the wafer W from the processing chamber 112 to the processing chamber 113. The processing chamber 113 is a magnetic field annealing device for performing annealing (heat treatment) on the wafer W in a state where a magnetic field is applied. The controller 200 controls the processing chamber 113 to perform magnetization and annealing on the wafer W. Here, the annealing temperature for heating the wafer W is set to be higher than the film formation temperature of the MgO film 209 (e.g., 150°C). For example, the wafer W is heated to 370°C or higher (preferably 400°C or higher and 500°C or lower) and subjected to annealing. Further, the annealing device performs annealing in a state where a magnetic field of 1T to 2T is applied, so that the magnetization is performed while controlling the magnetization directions of the first magnetic layer 204 and the second magnetic layer (the Co layer 206, the Mo layer 207, and the CoFeB layer 208).

FIG. 3B is a schematic diagram illustrating laminated films on the wafer W after the completion of step S104. The MgO film 209 and the CoFeB layer 208 are magnetized and crystallized by performing annealing in a magnetic field. The crystallization is schematically indicated by lattice hatching. At this time, boron B in the CoFeB layer 2008 is diffused to the Mo layer 207 or the Ta layer 202. The diffused boron 300 is schematically illustrated.

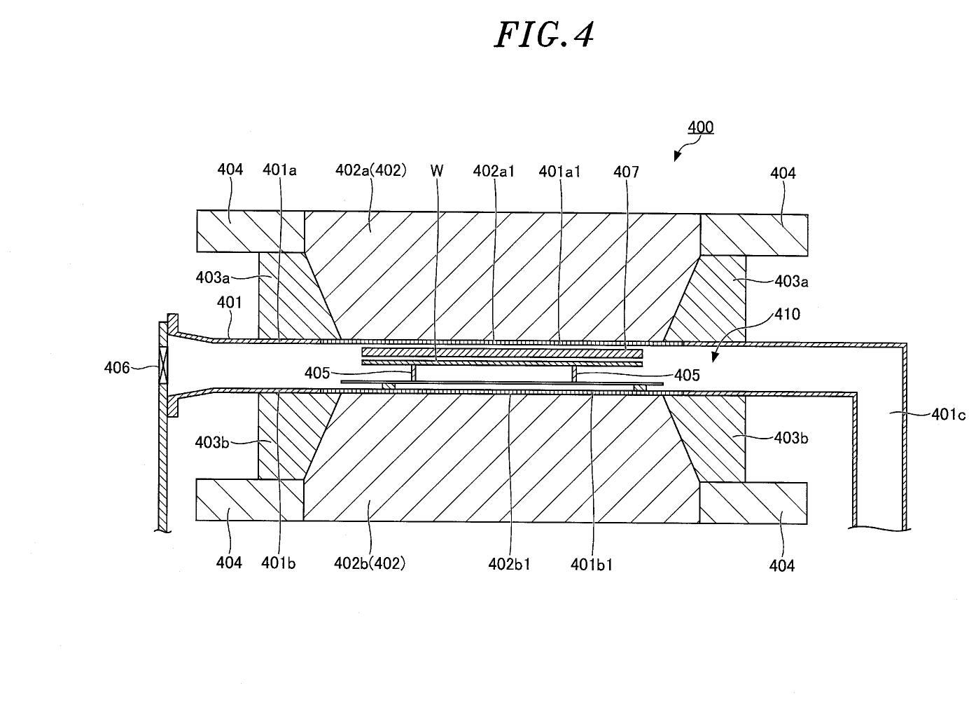

Here, an example of the magnetic field annealing device, which is the processing chamber 113, will be described with reference to FIG. 4. FIG. 4 is a cross-sectional view showing a configuration example of a magnetic field annealing device 400.

The magnetic field annealing device 400 is used for manufacturing an MRAM, and performs magnetization and annealing after the film formation of the fixed layer (CoFeB layer 2008) and the tunnel barrier layer (MgO film 209). The magnetic field annealing device 400 is provided as one processing chamber 113 of the substrate processing system 100 shown in FIG. 1.

The magnetic field annealing device 400 includes a processing chamber 401, a magnet 402, wires 403a and 403b, a yoke 404, a support 405, a gate valve 406, a heater 407, and a cooler (not shown).

The processing chamber 401 defines a processing space 410 for processing the wafer W. The processing chamber 401 includes a first wall 401a, a second wall 401b, and an exhaust line 401c. The first wall 401a includes a first heat insulating layer 401a1. The second wall 401b includes a second heat insulating layer 401b1. The exhaust line 401c is connected to an exhaust device (not shown), and a gas in the processing chamber 401 is exhausted through the exhaust line 401c.

The magnet 402 includes a first core portion 402a and a second core portion 402b. The first core portion 402a has a first end surface 402a1. The second core portion 402b has a second end surface 402b1.

The magnet 402 is an electromagnet, and may generate a magnetic field by supplying a current from a power supply (not shown) to the wires 403a and 403b. The wire 403a is a coated copper wire or the like wound around the first core portion 402a. The wire 403b is a coated copper wire or the like wound around the second core portion 402b. The first end surface 402a1 corresponds to a first magnetic pole of the magnet 402, and the second end surface 402b1 corresponds to a second magnetic pole of the magnet 402. The first magnetic pole and the second magnetic pole can be an N pole and an S pole, respectively, for example. The first end surface 402a1 and the second end surface 402b1 extend in parallel and face each other while being spaced apart from each other.

The wire 403a is disposed around the first core portion 402a, and the wire 403b is disposed around the second core portion 402b. The first core portion 402a and the second core portion 402b are made of a metal such as iron or the like, and magnetic field lines generated by the wires 403a and 403b converge on the first end surface 402a1 and the second end surface 402b1. Further, the magnet 402 is provided with a yoke 404.

The processing chamber 401 is disposed between the first end surface 402a1 of the magnet 402 and the second end surface 402b1 of the magnet 402. The first core portion 402a (the first end surface 402a1) of the magnet 402 is disposed on the first wall 401a of the processing chamber 401 outside the processing chamber 401, and the second core portion 402b of the magnet 402 is disposed on the second wall 401b (the second end surface 402b1) of the processing chamber 401 outside the processing chamber 401. The first wall 401a may be in contact with the first end surface 402a1. The second wall 401b may be in contact with the second end surface 402b1.

The first heat insulating layer 401a1 is disposed in the first wall 401a. The first heat insulating layer 401a1 is, e.g., a water-cooling jacket disposed in the first wall 401a. The first heat insulating layer 401a1 may be in contact with the first end surface 402a1. The second heat insulating layer 401b1 is disposed in the second wall 401b. The second heat insulating layer 401b1 is, e.g., a water-cooling jacket disposed in the second wall 401b. The second heat insulating layer 40 1b1 may be in contact with the second end surface 402b1. Both the water-cooling jacket of the first heat insulating layer 401a1 and the water-cooling jacket of the second heat insulating layer 401b1 have lines connected to a chiller unit (not shown). The chiller unit reduces heat transfer (insulates heat) between the processing chamber 401 and the magnet 402 by circulating cooling liquid through the first heat insulating layer 401a1 and the second heat insulating layer 401b1. The first heat insulating layer 401a1 and the second heat insulating layer 401b1 may have a fiber-based or foam-based heat insulating material, for example. In this case, the heat insulating material may be disposed between the first wall 401a and the first end surface 402a1 of the core portion 402a and between the second wall 401b and the second end surface 402b1 of the second core portion 402b.

The support 405 is disposed in the processing chamber 401. The wafer W is transferred into the processing space 410 by the vacuum transfer device 121 of the vacuum transfer chamber 120 through the gate valve 406 and supported by the support 405.

The magnetic field lines generated by the magnet 2 are perpendicular to the wafer W supported by the support 405 in the processing space 410. A magnetic field of about 0.1[T] to 2[T] can be generated at the wafer W by the magnet 402.

The heater 407 heats the wafer W supported by the support 405. The heater 407 is disposed in the processing chamber 401, and may be, e.g., a resistance heater, an infrared heater, a lamp heater, or the like.

The cooler (not shown) cools the wafer W supported by the support 405. The cooler may be, e.g., a gas supply device for supplying a cooling gas into the processing space 410. The cooling gas supplied into the processing space 410 cools the wafer W by exchanging heat with the wafer W. Then, the cooling gas is exhausted from the exhaust line 401c to the outside of the processing chamber 401. For example, a noble gas such as N₂ gas or He gas can be used as the cooling gas.

Accordingly, the magnetic field annealing device 400 can perform magnetization and annealing sheet by sheet.

Referring back to FIGS. 2 and 3, in step S105, a magnetic layer on the MgO film or the like is formed. For example, the controller 200 controls the vacuum transfer device 121 to transfer the wafer W from the processing chamber 113 to the processing chamber 114. The processing chamber 114 is, e.g., a PVD device, and a film is formed on the wafer W in the processing chamber 113. The controller 200 controls the processing chamber 114 and controls the processing chamber 111 such that desired laminated films are formed on the wafer W.

FIG. 3C is a schematic diagram illustrating laminated films of the wafer W after the completion of step S105. On the wafer W, a free layer (second magnetic layer) and a cap layer are formed on the crystallized MgO film 209.

The free layer is formed on the tunnel barrier layer. The free layer includes, e.g., a CoFeB layer 210, a Mo layer 211, and a CoFeB layer 212. The cap layer is formed on the free layer. The cap layer includes an MgO layer 213, a Ta layer 214, and an Ru layer 215.

Here, the CoFeB layers 210 and 212 formed by the PVD device have an amorphous structure.

In step S106, the wafer W is unloaded from the substrate processing system 100. For example, the controller 200 controls the vacuum transfer device 121 and the atmospheric transfer device 141 to transfer the processed wafer W to the carrier F. Then, the carrier F is removed from the load port 150.

In step S107, Ex-situ annealing is performed in a magnetic field. The processed wafer W is transferred to a batch type magnetic field annealing device (not shown). The batch-type magnetic field annealing device performs annealing (heat treatment) on the wafer W in a state where a magnetic field is applied to a plurality of wafers W.

FIG. 3D is a schematic diagram illustrating laminated films on the wafer W after the completion of step S107. Due to the magnetic field annealing, the magnetization is performed while controlling the magnetization directions of the CoFeB layer 210, the Mo layer 211, and the CoFeB layer 212. The CoFeB layers 210 and 212 are crystallized. The crystallization is schematically indicated by lattice hatching. At this time, boron B in the CoFeB layers 210 and 212 are diffused to the Mo layer 211 and the Ta layer 214. The diffused boron 300 is schematically shown.

Here, the crystallization of the MgO film 209 prevents boron B in the CoFeB layers 210 and 212 from penetrating through the MgO film 209 and diffusing to the Mo layer 207 and the Ta layer 202. Further, the crystallization of the MgO film 209 prevents boron B in the CoFeB layer 208 from penetrating through the MgO film 209 and diffusing to the Mo layer 211 and the Ta layer 214.

Here, an MTJ element forming method according to a reference example will be described. In the MTJ element forming method according to the reference example, the fixed layer (the CoFeB layer 208), the tunnel barrier layer (the MgO film 209), and the free layer (the CoFeB layer 210) are formed and, then, Ex-situ annealing is performed in a magnetic field by the batch-type magnetic field annealing device.

At this time, boron B in the CoFeB layer 208 penetrates through the MgO film 209 and diffuses to the Mo layer 211 and the Ta layer 214. Further, boron B in the CoFeB layer 210 penetrates through the MgO film 209 and diffuses to the Mo layer 207 and the Ta layer 202. The penetration of boron B through the MgO film 209 causes pinholes, and the state of the interface between the MgO film 209 and the CoFeB layer 208 (210) deteriorates. Accordingly, the characteristics of the MTJ element may deteriorate. For example, the insulation performance of the MgO film 209 may deteriorate.

On the other hand, in an MTJ element forming method according to the present embodiment, the fixed layer (the CoFeB layer 208) and the tunnel barrier layer (the MgO film 209) are formed and, then, In-situ annealing is performed in a magnetic field, so that boron B in the CoFeB layer 208 diffuses to the Mo layer 207 and the Ta layer 202. On the other hand, in the annealing of step S104, the Mo layer 211 and the Ta layer 214 are not yet formed on the MgO film 209, so that it is possible to prevent boron B in the CoFeB layer 288 from penetrating through the MgO film 209 and diffusing. Accordingly, the penetration of boron B through the MgO film 209 is suppressed, and the deterioration of the state of the interface between the MgO film 209 and the CoFeB layer 208 is suppressed.

After the free layer (CoFeB layer 210) is formed, Ex-situ magnetic field annealing is performed by the batch type magnetic field annealing device. Here, the MgO film 209 is crystallized by the annealing of step S104. Accordingly, the penetration of boron B penetrating through the MgO film 209 is suppressed, and the deterioration of the state of the interface between the MgO film 209 and the CoFeB layers 208 and 210 is suppressed.

In the MTJ element forming method according to the present embodiment, after the formation of the free layer (CoFeB layer 210) and the cap layer, Ex-situ annealing is performed in a magnetic field by the batch type magnetic field annealing device. However, the present disclosure is not limited thereto. After the film formation of the free layer and the cap layer, In-situ magnetic field annealing may be performed by a single-wafer magnetic field annealing device. For example, after the free layer and the cap layer are formed in step S105, the controller 200 controls the vacuum transfer device 121 to transfer the wafer W from the processing chamber 114 to the processing chamber 115. Similarly to the processing chamber 113, the processing chamber 115 is a magnetic field annealing device for performing annealing on the wafer W in a state where a magnetic field is applied. The controller 200 may be configured to control the processing chamber 115 to perform magnetization and annealing on the wafer W.

Due to the annealing performed after the film formation of the fixed layer (CoFeB layer 208) and the tunnel barrier layer (MgO film 209), which is shown in step S104, the CoFeB layer 208 and the MgO film 209 may be annealed such that the penetration of boron B is suppressed. Due to the annealing performed after the film formation of the free layer (CoFeB layer 210) and the cap layer, which is shown in step S107, the CoFeB layer 208, the MgO film 209, and the CoFeB layer 210 may be crystallized.

The annealing performed after the film formation of the fixed layer (the CoFeB layer 208) and the tunnel barrier layer (the MgO film 209), which is shown in step S104, may be performed without applying a magnetic field. The annealing performed after the formation of the free layer (the CoFeB layer 210) and the cap layer, which is shown in step S107, may be performed while applying a magnetic field. Accordingly, due to the annealing in step S104, the CoFeB layer 208 and the MgO film 209 may be annealed such that the penetration of boron B is suppressed, and due to the annealing in step S107, the CoFeB layers 208 and 210 may be magnetized and the CoFeB layers 208 and 210 and the MgO film 209 may be crystallized.

While the substrate processing system and the vacuum processing apparatus according to the embodiments have been described, they are not limited to the above-described embodiments and may be variously changed and modified without departing from the scope of the present disclosure. The above-described embodiments may be combined without contradicting each other.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1. A film forming method for forming a laminated structure on a substrate to form a magnetic tunnel junction element, comprising:
an operation of forming a first magnetic layer on the substrate and forming an insulating layer on the first magnetic layer;
an operation of performing first magnetic field annealing by applying a magnetic field to the substrate on which the first magnetic layer and the insulating layer have been formed after the insulating layer is formed but before a second magnetic layer is formed on the insulating layer;
an operation of forming the second magnetic layer on the insulating layer after the operation of performing first magnetic field annealing, and
an operation of performing second magnetic field annealing by applying the magnetic field to the substrate on which the second magnetic layer has been formed after the second magnetic layer is formed.

2. The film forming method of claim 1, wherein in the operation of performing the first magnetic field annealing by applying the magnetic field to the substrate, the first magnetic layer and the insulating layer are crystallized.

3. The film forming method of claim 1, wherein in the operation of performing the first magnetic field annealing by applying the magnetic field to the substrate, a magnetization direction of the first magnetic layer is controlled.

4. The film forming method of claim 2, wherein in the operation of performing the first magnetic field annealing by applying the magnetic field to the substrate, a magnetization direction of the first magnetic layer is controlled.

5. The film forming method of claim 1, wherein in the operation of performing the first magnetic field annealing by applying the magnetic field to the substrate, 1T to 2T of the magnetic field is applied to the substrate on which the first magnetic layer and the insulating layer have been formed.

6. The film forming method of claim 1, wherein in the operation of performing the second magnetic field annealing by applying the magnetic field to the substrate, 1T to 2T of the magnetic field is applied to the substrate on which the second magnetic layer has been formed.
